(19) United States
(12) Patent Application Publication
(10) Pub. No.: US 2009/0179153 A1
(43) Pub. Date: Jul. 16, 2009

(54) Alternate PMT Shield Method

(75) Inventor: Anthony P. Del Medico, Niles, IL (US)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Siemens Medical Solutions USA, Inc., Malvern, PA (US)

(21) Appl. No.: 11/972,869

(22) Filed: Jan. 11, 2008

(51) Int. Cl. G01T 1/166; H05K 9/00

(52) U.S. Cl. 250/363.04; 361/816

(57) ABSTRACT

A detector includes a scintillator, a light guide, at least one photomultiplier, and a shield for the at least one photomultiplier. The at least one photomultiplier may be supported by a non-magnetic material. The shield includes a magnetic shield in front of the scintillator and a magnetic shield enclosing the at least one photomultiplier.

### TECHNICAL FIELD

The technical field of the present invention relates to a device and method for shielding photomultiplier tubes (PMT). More particularly, the hereinafter described device and method allows a PMT of a photon detector, such as a single photon emission computer tomography gamma camera detector, to be shielded from magnetic fields, such as the magnetic field of the earth.

### BACKGROUND

Medical devices, such as, for example nuclear or scintillation or gamma cameras are conventionally used to perform Single Photon Emission Computed Tomography (SPECT) studies. A patient ingests a radiopharmaceutical, such as for example Thallium or Technetium, which emits gamma radiation from a body organ which is the subject of a medical study. The gamma camera detects the radiation and generates data indicative of the position and energy of the radiation which is then mathematically corrected, refined and processed through a procedure known as reconstruction tomography (performed by a computer) to produce pictures of scintigrams (two or three dimensional) of the body organ which is the subject of the study. Different radiopharmaceuticals produce gamma rays having different energies typically expressed as photopeak energy in electron volts corresponding to the output pulse generated by a photomultiplier tube (PMT) in response to a scintillation produced by a crystal when struck by a gamma ray.

PMT's are extremely sensitive detectors of light in the ultraviolet, visible and near infrared. These detectors multiply the signal produced by incident light by as much as 10⁸, from which single photons can be resolved. The combination of high gain, low noise, high frequency response and large area of collection have meant that these devices find applications in medical imaging scanning.

Photomultipliers 107 may comprise, as shown by FIG. 1, a glass vacuum tube which houses a photocathode 102, several dynodes 103, and an anode 104. Incident photons 101 strike the photocathode material which may be present as a thin deposit on the entry window of the device, with electrons 105 being produced as a consequence of the photoelectric effect. These electrons 105 are directed by the focusing electrode 106 towards the electron multiplier, where electrons are multiplied by the process of secondary emission.

The electron multiplier consists of a number of electrodes, called dynodes 103. Each dynode 103 is held at a more positive voltage than the previous one. The electrons 105 leave the photo-cathode 102, having the energy of the incoming photon 101 (minus the work function of the photo-cathode 102). As they move towards the first dynode they are accelerated by the electric field and arrive with much greater energy. On striking the first dynode, more low energy electrons are emitted and these, in turn, are accelerated toward the second dynode. The geometry of the dynode chain is such that a cascade occurs with an ever-increasing number of electrons being produced at each stage. Finally the anode 104 is reached where the accumulation of charge results in a sharp current pulse indicating the arrival of a photon 101 at the photo-cathode.

Photomultipliers used in a location with high magnetic fields may be affected by the magnetic fields. The path of the electron may be curved because of magnetic fields in the same location as the photomultiplier. Consequently, a photomultiplier may be shielded from magnetic fields to improve its light responsive function. This shielding may be made by the use of a layer of mu-metal. Mu-metal is a nickel-iron alloy (for example 75% nickel, 15% iron, plus copper and molybdenum) that has very high magnetic permeability. The high permeability makes mu-metal very effective at screening static or low-frequency magnetic fields, which cannot be attenuated by other methods. Mu-metal requires special heat treatment, such as annealing in hydrogen atmosphere, which may increase the magnetic permeability about 40 times. The annealing alters the material's crystal structure, aligning the grains and removing some impurities, especially carbon. Mechanical treatment may disrupt the material's grain alignment, leading to drop of permeability in the affected areas, which can be restored by repeating of the hydrogen annealing step.

One disadvantage with using mu-metal to shield PMT's is the inherent creation of fringe fields at the end of the shielding structure boarding to air. The magnetic flux lines created at the boundary of mu-metal to air may be preferably avoided, because the magnetic field may influence the electrons and alter the light response function of the PMT, especially when the the detector is rotated.

A further magnetic field that may influence the electrons and alter the light response function of the PMT is the magnetic field of the earth. Consequently, the detector may preferably be shielded from the magnetic field of the earth.

In view of the prior art discussed above, there is a need to provide a device and method allowing for shielding PMT's from magnetic fields. This would improve the uniformity of the images taken. Further, there is a need to provide a fringe free shield for PMT's. Further, magnetic fields at the side of a PMT caused by fringe fields from a front edge of a nest assembly for PMT's is to be avoided. This would improve image quality of the images taken.

It may be desirable to have an efficient and sensitive PMT. This would allow for a reduction in time for taking an image, an improved quality of the images, and a reduction of exposure of the subject to the image apparatus.

There also exists a need to minimize the structure of the detector and it is desirable to have a light detector. Small and light detectors can be easily moved around the subject and in the medical device.

Additionally, it is desirable to avoid cumbersome arrangements for avoiding or compensating fringe fields, in an economic and technical perspective. Additionally, it is desirable to avoid cumbersome arrangements, in an economic and technical perspective, for shielding the detector from magnetic fields.

### SUMMARY

According to an embodiment, a single photon emission computer tomography gamma camera detector may comprise a scintillator; a flat surface light guide; at least one photomultiplier tube; and a shield for at least one photomultiplier tube; wherein the at least one photomultiplier tube is supported by a non-magnetic material, and the shield is a magnetic shield in front of the scintillator and a magnetic shield enclosing the at least one photomultiplier tube together with the magnetic shield in front of the scintillator.

According to another embodiment, a method for shielding a photomultiplier tube in a single photon emission computer tomography gamma camera detector comprising a scintillator; a flat surface light guide; at least one photomultiplier tube; and a shield for at least one photomultiplier tube; wherein the method may comprise the steps of: supporting the at least one photomultiplier tube with a non-magnetic material; and forming a shield of magnetic material in front of the scintillator and forming a magnetic shield enclosing the at least one photomultiplier tube together with the magnetic shield in front of the scintillator.

According to another embodiment, a detector may comprise scintillator means; light guide means; at least one photomultiplier means; and shield means for the at least one photomultiplier means; wherein the at least one photomultiplier means is supported by a non-magnetic material, and the shield means is a magnetic shield in front of the scintillator means and a magnetic shield enclosing the at least one photomultiplier means together with the magnetic shield in front of the scintillator means.

According to a further embodiment, the non-magnetic material may be stainless steel or aluminum. According to a further embodiment, the shield may comprise mu-metal. According to a further embodiment, the structure of the non-magnetic material supporting the photomultiplier tube may comprise a nested array structure of cylindrical sleeves around each PMT. According to a further embodiment, the shape of the shield may be adapted to enclose the detector. According to a further embodiment, the non-magnetic material supporting may support a plurality of the photomultipliers. According to a further embodiment, the light guide may comprise a plurality of light guides, each being tapered for contact with an associated photomultiplier tube.

Other technical advantages of the present disclosure will be readily apparent to one skilled in the art from the following description and claims. Various embodiments of the present disclosure obtain only a subset of the advantages set forth. No one advantage is critical to the embodiments. Any claimed embodiment may be technically combined with any preceding claimed embodiment(s).

### BRIEF DESCRIPTION OF THE DRAWINGS

The accompanying drawings, which are incorporated in and constitute a part of the specification, illustrate exemplary embodiments, and together with the general description given above and the detailed description of the exemplary embodiments given below, serve to explain, by way of example, the principles of the invention.

FIG. 1 shows the working principles of a photomultiplier tube according to prior art.

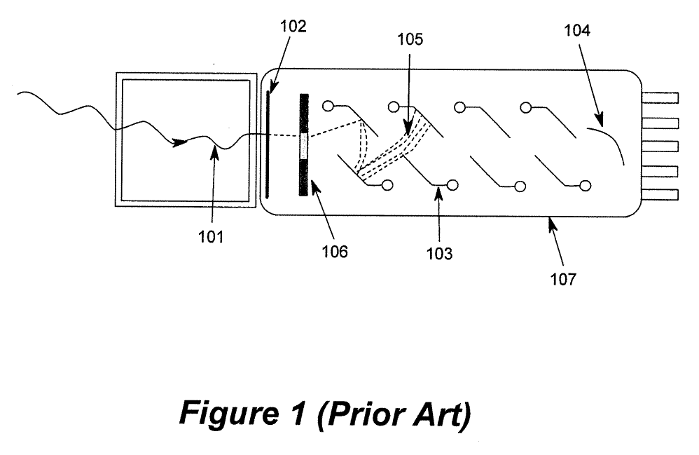

FIG. 2 shows a detector according to one embodiment.

FIG. 3 shows a view of section A-A according to the embodiment shown in FIG. 2.

FIG. 4 shows another embodiment of a part of a detector.

FIG. 5 shows another view of the embodiment shown in FIG. 4.

FIG. 6 shows a flow chart of a method for shielding a PMT according to an embodiment.

### DETAILED DESCRIPTION

The hereinafter described embodiments may provide a detector and method allowing for shielding at least one PMT from magnetic fields. The shielding of the PMT's in these embodiments may improve image quality, such as for example the uniformity of the images taken. Further, hereinafter described embodiments may provide a fringe free shield for PMT's. Further, hereinafter described embodiments may avoid magnetic fields at the side of a PMT caused by fringe fields from a front edge of a nest assembly for PMT's. Such shielding and avoidance of fringe fields may improve image quality of the images taken.

Embodiments may render a PMT efficient and sensitive. This may result in a reduction in time for taking an image, an improved quality of the images, and a reduction of exposure of the subject to the image apparatus.

Embodiments may minimize the structure of the detector and may provide for a light detector. Small and light detectors can be easily moved around the subject and by the medical device carrying the detector.

Embodiments may avoid cumbersome arrangements for avoiding or compensating fringe fields, in an economic and technical perspective. The hereinafter described embodiments may avoid cumbersome arrangements, in an economic and technical perspective, for shielding the detector from magnetic fields.

A problem is that image quality, such as image uniformity, decreases if the PMT's are affected by magnetic fields. In other words, the basic light response function of a PMT is affected by magnetic fields. In embodiments PMT's may be shielded from magnetic fields to improve image quality.

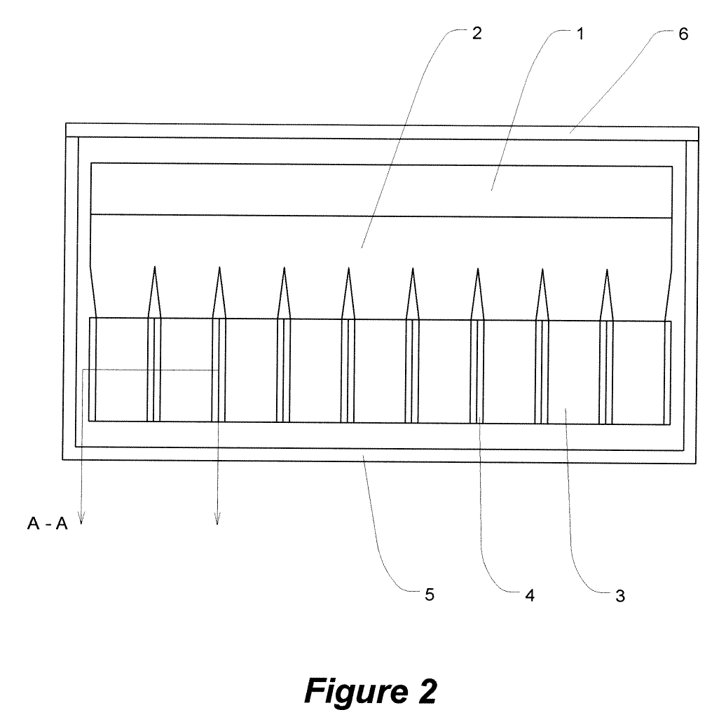

FIG. 2 shows a detector according to one embodiment. The detector may be a single photon emission computer tomography gamma camera detector or any other detectors, such as, for example, nuclear or scintillation or gamma detectors used in medical devices for performing Single Photon Emission Computed Tomography (SPECT) studies. The detector may function as a camera for taking images of a subject. The detector may include a scintillator 1. The scintillator is a substance that absorbs high energy electromagnetic or charged particle radiation and, in response, fluoresces photons. In other words, the scintillator converts the energy to light of a wavelength which can be detected by, for example photomultiplier tubes. The scintillator may be an inorganic crystal, organic plastics, liquid, or a combination hereof. An example hereof may be thallium-doped sodium iodide crystals.

As shown in FIG. 2, the detector may further include a light guide 2, such as a flat surface light guide made out of Plexiglas or other suitable material. The scintillator 1 is arranged on one side of the light guide 2, and at least one photomultiplier tube 3 (PMT) is arranged on the opposite side of the light guide 2. According to an embodiment, the light guide may be a single piece light guide 2 and may have a plurality of tapered ends as shown in FIG. 2, each facing an associated photomultiplier tube 3. According to another embodiment, a plurality of light guides for each photomultiplier tube 3 may be used. Each single light guide may have a tapered end as shown in FIG. 2. By this arrangement a photon incident to the scintillator 1 is converted to a current pulse when going through the scintillator 1, the light guide 2 and the PMT 3.

In the embodiment shown by FIG. 2, the shielding may comprise a magnetic material. This shield may comprise one shield 6 in front of the scintillator and one shield 5 around the rest of the detector. The shield 6 shields in this way the front of the scintillator 1 of the detector. That is the side facing the incident radiation. The shield 6 may be in direct contact with the scintillator 1 or may be at a distance to the scintillator 1. The shield 5 shields the remaining part of the detector comprising the PMT's by enclosing the PMT's. In this way the shield 5 and the shield 6 completely enclose at least the PMT's in the detector. In other words, the shield is a magnetic shield 6 in front of the scintillator and a magnetic shield 5 enclosing the PMT's together with the magnetic shield 6 in front of the scintillator. Hereby magnetic fields are not affecting the PMT's. A suitable magnetic material for the shields 5 and 6 may be mu-metal.

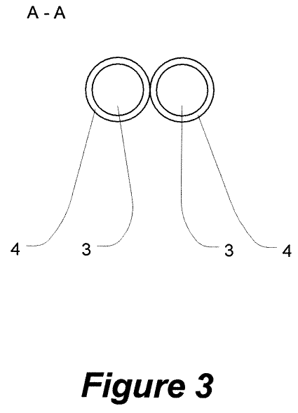

In the embodiment shown by FIGS. 2 and 3, the PMT's 3 may be supported by a nested array structure of cylindrical sleeves 4. These sleeves 4 may be arranged around each PMT 3. FIG. 3 shows a view of section A-A according to the embodiment shown in FIG. 2. In this embodiment the cylindrical sleeves 4 are arranged around each PMT 3. The sleeves 4 may be connected to other neighboring sleeves. The sleeves need not to be cylindrical, but may have any complimentary shape to that of the PMT. The sleeves may be made out of a non-magnetic material. No fringe field is created at the boundary to air of the sleeves 4, because the sleeves 4 are made of a non-magnetic material. Hereby the shield 5 and 6 of embodiments described do not cause any fringe fields affecting the PMT's. In embodiments, the sleeves may provide a fringe free support for PMT's. In this way magnetic fields may be avoided at the side, for example the photo-cathode side, of a PMT caused by fringe fields from a front edge of a nest magnetic assembly for PMT's. An effect hereof may be improved image quality of the images taken.

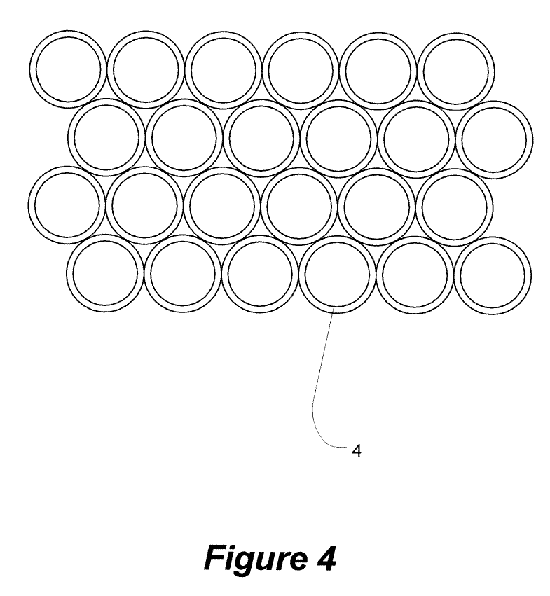

FIG. 4 shows an embodiment of a part of a detector. Here the sleeves 4 supporting a PMT (not shown in FIG. 4) are arranged in a nested array structure of cylindrical sleeves.

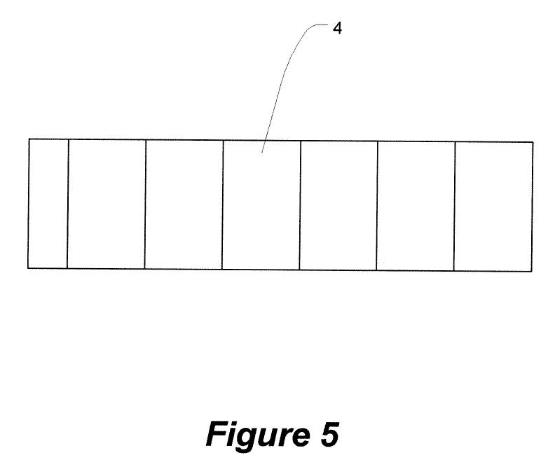

FIG. 5 shows a side view of the embodiment shown in FIG. 4. Here a front row of six sleeves 4 are shown with a half of a sleeve 4 shown from a second row behind the first row of sleeves.

In a more specific embodiment, a detector, such as a SPECT gamma camera, employs an array of PMT's to convert the collection of light from a sodium iodide crystal into an electrical signal matrix. The resulting electrical signal is then processed to provide and indication of both position (in the form of an XY coordinate) and an energy signal. The PMT assembly converts the light photons from the crystal into an electron cloud at the photo-cathode side of the PMT. The resulting electrons are then accelerated into the first dynode. The first dynode is biased positive with respect to the photo-cathode so that the electrons produced by the photo-cathode are attracted to the first dynode and thus collide with the dynode. The collision of the electrons with the first dynode results in the emission of electrons from the first dynode and is in turn accelerated to the following dynodes in the PMT structure. This action results in the multiplication of the initial electrons produced by the photo-cathode. The electron optics at the photo-cathode to first dynode is electrostatic and determines the basic light response function of the PMT. However, the fundamental characteristic of the electron trajectory is also susceptible to magnetic fields such as the magnetic field of the earth (or a magnetic field in the order of at least one gauss). That is, the magnetic field can deflect the electron and this alters the light response function of the PMT as the SPECT gamma camera is rotated. This susceptibility then results in an alteration of the gamma cameras image uniformity. In order to minimize the effects of magnetic fields the gamma camera thus needs to be shielded from magnetic fields. Magnetic fields affecting the gamma camera are, among others, the magnetic field of the earth and fringe fields created at the boundary to air of a ferrous material. To overcome this in this more specific embodiment, the camera may be shielded by forming a shield of magnetic material in front of the scintillator and enclosing with the shield the at least one PMT. Additionally, to avoid magnetic fields, such as the fringe fields, the PMT's may be supported with a non-magnetic material.

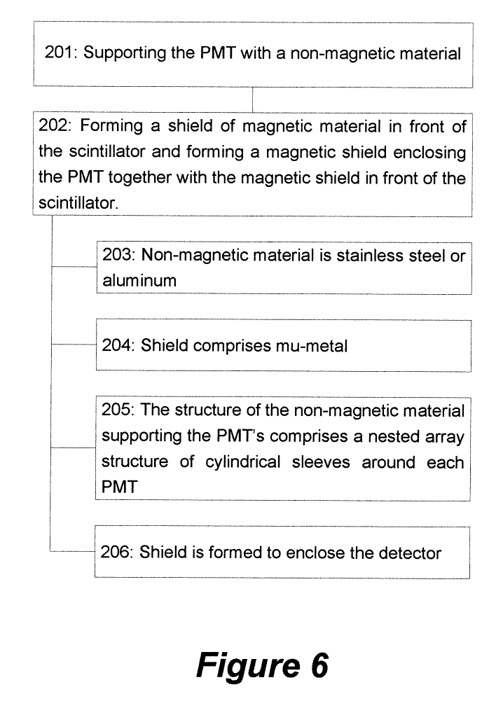

FIG. 6 shows a flow chart of a method for shielding a PMT according to an embodiment. The method may comprise the following steps 201 to 206 taken in any order. One step, indicated as 201 in FIG. 6, is to support the PMT with a non-magnetic material. Another step, indicated as 202 in FIG. 6, is to form a shield of magnetic material in front of the scintillator and to form a magnetic shield enclosing the at least one photomultiplier tube together with the magnetic shield in front of the scintillator. Hereby a shield of magnetic material in front of the scintillator and around the detector is provided. In this way the PMT's are completely surrounded by a shield of magnetic material. Furthermore, no magnetic field, such as a fringe field, is created that can influence the light response function of the PMT's, because the PMT's are supported by a non-magnetic material.

In further embodiments, the method may include that the non-magnetic material comprises stainless steel or aluminum. In this respect, please see step 203 in FIG. 6. In yet further embodiments, the method may include that the shield comprises mu-metal. In this respect, please see step 204 in FIG. 6. The shape of the shield may also be formed to enclose the detector. In this respect, please see step 206 in FIG. 6. In a further embodiment, the method may include that the structure of the non-magnetic material supporting the PMT's comprises a nested array structure of cylindrical sleeves around each PMT. In this respect, please see step 205 in FIG. 6.

At least one of the embodiments herein disclosed may overcome the problem with providing shielding of magnetic fields. If magnetic shielding was to be made by placing a cylindrical sleeve of shielding magnetic material around each PMT in the array, then a satisfying result might be achieved when the edge of the shield is able to go past the front of the PMT and the first dynode voltage is sufficiently high. However, a detector may have a flat surface light guide and varying first dynode voltage. The flat surface light guide causes the edge of the shield to be at or slightly behind the front of the PMT at the photo-cathode side. This results in a less than optimal shielding. At least one of the embodiments herein disclosed may overcome this problem by supporting the PMT's with a non-magnetic material and forming a shield of magnetic material in front of the scintillator and enclosing with the shield the PMT's. Hereby a shielding geometry may be provided that is not susceptible to the edge boundary effect at the front of the PMT photo-cathode.

At least one of the embodiments herein disclosed may overcome the problem with fringe fields that may exist at the front of the PMT's photo-cathode surface caused by a magnetic shield arranged around the PMT's directly. The fringe fields are avoided by using a non-magnetic material (such as stainless steel) to support the PMT's and then placing a magnetic shield in front of the crystal and around and enclosing the gamma camera detector assembly. This enclosure then deflects the magnetic field of the earth around the detector assembly and avoids having a strong fringe field in the vicinity of the PMT photo-cathode.

The detector and method discussed above shields PMT's from magnetic fields. The exemplary embodiments are well adapted to carry out the objects and attain the ends and advantages mentioned, as well as others inherent therein. While the disclosure has been described and is defined by reference to specific exemplary embodiments, such references do not imply a limitation, and no such limitation is to be inferred. The disclosure is capable of considerable modification, alteration, and equivalents in form and function, as will occur to those ordinarily skilled in the pertinent arts. The described embodiments are exemplary only, and are not exhaustive of the scope of the disclosure. Consequently, the disclosure is intended to be limited only by the spirit and scope of the appended claims, giving full cognizance to equivalents in all respects.

1. A single photon emission computer tomography gamma camera detector comprising:
a scintillator;
a flat surface light guide;
a photomultiplier tube (PMT);
a shield; and
non-magnetic material configured to support the PMT;
wherein the shield comprises a first magnetic shield portion positioned in front of the scintillator and a second magnetic shield portion, the first and second magnetic shield portions together enclosing the PMT.

2. The detector according to claim 1, wherein the non-magnetic material comprises stainless steel or aluminum.

3. The detector according to claim 1, wherein the shield comprises mu-metal.

4. The detector according to claim 1, further comprising a plurality of PMTs, each PMT supported by non-magnetic material, wherein the non-magnetic material is structured in a nested array of cylindrical sleeves encircling respective PMTs.

5. The detector according to claim 1, wherein the shape of the shield is configured to enclose the detector.

6. The detector according to claim 1, wherein the non-magnetic material supports a plurality of the photomultipliers.

7. The detector according to claim 6, wherein the light guide comprises a plurality of light guides, each being tapered for contact with an associated photomultiplier tube.

8. A method for shielding a photomultiplier tube in a single photon emission computer tomography gamma camera detector having a scintillator, a flat surface light guide and a photomultiplier tube, the method comprising:
supporting the photomultiplier tube with a non-magnetic material; and
forming a first magnetic shield portion of magnetic material in front of the scintillator and forming a second magnetic shield portion, the first and second magnetic shield portions together enclosing the photomultiplier tube.

9. The method according to claim 8, wherein the non-magnetic material comprises stainless steel or aluminum.

10. The method according to claim 8, wherein the shield comprises mu-metal.

11. The method according to claim 8, wherein the detector further comprises a plurality of photomultiplier tubes, and the step of supporting comprises forming a nested array of cylindrical sleeves around respective photomultiplier tubes.

12. The method according to claim 8, wherein the shape of the shield is formed to enclose the detector.

13. The method according to claim 8, wherein the non-magnetic material supports a plurality of the photomultipliers.

14. The method according to claim 13, wherein the light guide comprises a plurality of light guides, each being tapered for contact with an associated photomultiplier tube.

15. A detector comprising:
means for scintillation;
means for guiding light;
photomultiplier means for photomultiplication; and
means for shielding the means for photomultiplication;
wherein the means for photomultiplication is supported by a non-magnetic material, and the means for shielding encloses the means for photomultiplication.

16. The detector according to claim 15, wherein the non-magnetic material comprises stainless steel or aluminum.

17. The detector according to claim 15, wherein the means for shielding comprises mu-metal.

18. The detector according to claim 15, wherein the the non-magnetic material comprises a nested structure of sleeves.

19. The detector according to claim 15, wherein the means for shielding encloses the detector.

20. The detector according to claim 15, wherein the non-magnetic material supports a plurality of means for photomultiplication.
